(19) United States
(12) Patent Application Publication
(10) Pub. No.: US 2025/0301702 A1
(43) Pub. Date: Sep. 25, 2025

(54) WIRING STRATEGY FOR STACK FET S/D CONTACTS

(71) Applicant: International Business Machines Corporation, Armonk, NY (US)

(72) Inventors: Gopal Sankar Kenath, Troy, NY (US); Tao Li, Slingerlands, NY (US); Ruilong Xie, Niskayuna, NY (US); Nicolas Jean Loubet, GUILDERLAND, NY (US)

(21) Appl. No.: 18/612,001

(22) Filed: Mar. 21, 2024

(51) Int. Cl. H01L 29/417; H01L 23/522; H01L 23/528; H01L 27/06; H01L 27/092; H01L 29/06; H01L 29/423; H01L 29/775; H01L 29/786

(52) U.S. Cl. CPC H10D 30/6729; H01L 23/5226; H01L 23/5283; H10D 30/43; H10D 30/6735; H10D 30/6756; H10D 62/121; H10D 84/856; H10D 88/00

(57) ABSTRACT

A microelectronic structure that includes a stacked FET that includes a frontside source/drain and a backside source/drain. A connection via that passes through the backside source/drain. The connection via extends from a frontside surface of the backside source/drain to a backside surface of the backside source/drain. The backside source/drain surrounds the connection via as it passes through the backside source/drain.

### BACKGROUND

The present invention generally relates to the field of microelectronics, and more particularly to forming the necessary connections for a stack FET.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form the necessary connections for a stack FET.

### BRIEF SUMMARY

Additional aspects and/or advantages will be set forth in part in the description which follows and, in part, will be apparent from the description, or may be learned by practice of the invention.

A microelectronic structure that includes a stacked FET that includes a frontside source/drain and a backside source/drain. A connection via that passes through the backside source/drain. The connection via extends from a frontside surface of the backside source/drain to a backside surface of the backside source/drain. The backside source/drain surrounds the connection via as it passes through the backside source/drain.

A microelectronic structure includes a stacked FET that includes a first frontside source/drain, a second frontside source/drain, a first backside source/drain, and a second backside source/drain. A first wiring scheme is utilized to make connections to the first frontside source/drain and the first backside source/drain and a second wiring scheme is utilized to make connections to the second frontside source/drain and the second backside source/drain. The first wiring scheme and the second wiring scheme are different wiring schemes. The first wiring scheme includes a first connection via that passes through the first backside source/drain. The first connection via extends from a frontside surface of the first backside source/drain to a backside surface of the first backside source/drain. The first backside source/drain surrounds the first connection via as it passes through the first backside source/drain.

A microelectronic structure includes a stacked FET that includes a first frontside source/drain a second frontside source/drain, a first backside source/drain, and a second backside source/drain. A first wiring scheme is utilized to make connections to the first frontside source/drain and the first backside source/drain and a second wiring scheme is utilized to make connections to the second frontside source/drain and the second backside source/drain. The first wiring scheme and the second wiring scheme are different wiring schemes. The first wiring scheme includes a connection via that passes through the first backside source/drain. The connection via extends from a frontside surface of the first backside source/drain to a backside surface of the first backside source/drain. The first backside source/drain surrounds the connection via as it passes through the first backside source/drain. A backside connection located on the backside surface of the first backside source/drain. The backside connection extends laterally across the backside surface of the first backside source/drain. A backside cap located on the backside surface of a backside connection. The second wiring scheme includes a backside contact in contact with a backside side surface of the second backside source/drain. A backside power distribution network is connected to the backside contact.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet stacked FET, in accordance with the embodiment of the present invention.

FIG. 2 illustrates a cross section X of the nanosheet stacked FET after initial frontside processing, in accordance with the embodiment of the present invention.

FIG. 3 illustrates a cross section Y1 of the source/drain region of the first wiring scheme after initial frontside processing, in accordance with the embodiment of the present invention.

FIG. 4 illustrates a cross section Y2 of the source/drain region of the second wiring scheme after initial frontside processing, in accordance with the embodiment of the present invention.

FIG. 5 illustrates a cross section Y3 of the source/drain region of the third wiring scheme after initial frontside processing, in accordance with the embodiment of the present invention.

FIG. 6 illustrates a cross section X of the nanosheet stacked FET after formation of the first and second connection via trenches, in accordance with the embodiment of the present invention.

FIGS. 7A and 7B illustrate a cross section Y1 of the source/drain region of the first wiring scheme after formation of a first connection via trench, in accordance with the embodiment of the present invention.

FIGS. 8A and 8B illustrate a cross section Y2 of the source/drain region of the second wiring scheme after formation of a second connection via trench, in accordance with the embodiment of the present invention.

FIG. 9 illustrates a cross section Y3 of the source/drain region of the third wiring scheme after formation of a first and second connection via trench, in accordance with the embodiment of the present invention.

FIG. 10 illustrates a cross section X of the nanosheet stacked FET after formation of the frontside source/drain contact trenches, in accordance with the embodiment of the present invention.

FIG. 11 illustrates a cross section Y1 of the source/drain region of the first wiring scheme after formation of the frontside source/drain contact trenches, in accordance with the embodiment of the present invention.

FIG. 12 illustrates a cross section Y2 of the source/drain region of the second wiring scheme after formation of the frontside source/drain contact trenches, in accordance with the embodiment of the present invention.

FIG. 13 illustrates a cross section Y3 of the source/drain region of the third wiring scheme after formation of the frontside source/drain contact trenches, in accordance with the embodiment of the present invention.

FIG. 14 illustrates a cross section X of the nanosheet stacked FET after formation of the frontside source/drain contacts and the formation of the connection vias, in accordance with the embodiment of the present invention.

FIG. 15 illustrates a cross section Y1 of the source/drain region of the first wiring scheme after formation of the frontside source/drain contacts and the formation of the connection vias, in accordance with the embodiment of the present invention.

FIG. 16 illustrates a cross section Y2 of the source/drain region of the second wiring scheme after formation of the frontside source/drain contacts and the formation of the connection vias, in accordance with the embodiment of the present invention.

FIG. 17 illustrates a cross section Y3 of the source/drain region of the third wiring scheme after formation of the frontside source/drain contacts and the formation of the connection vias, in accordance with the embodiment of the present invention.

FIG. 18 illustrates a cross section X of the nanosheet stacked FET after formation of the back-end-of-the-line layer and the carrier wafer, and flipping the nanosheet stacked FET over for backside processing, in accordance with the embodiment of the present invention.

FIG. 19 illustrates a cross section Y1 of the source/drain region of the first wiring scheme after formation of the back-end-of-the-line layer and the carrier wafer, and flipping the nanosheet stacked FET over for backside processing, in accordance with the embodiment of the present invention.

FIG. 20 illustrates a cross section Y2 of the source/drain region of the second wiring scheme after formation of the back-end-of-the-line layer and the carrier wafer, and flipping the nanosheet stacked FET over for backside processing, in accordance with the embodiment of the present invention.

FIG. 21 illustrates a cross section Y3 of the source/drain region of the third wiring after formation of the back-end-of-the-line layer and the carrier wafer, and flipping the nanosheet stacked FET over for backside processing, in accordance with the embodiment of the present invention.

FIG. 22 illustrates a cross section X of the nanosheet stacked FET after removal of the first substrate, the etch stop, and the second substrate, and the formation of backside interlayer dielectric layer, in accordance with the embodiment of the present invention.

FIG. 23 illustrates a cross section Y1 of the source/drain region of the first wiring scheme after removal of the first substrate, the etch stop, and the second substrate, and the formation of backside interlayer dielectric layer, in accordance with the embodiment of the present invention.

FIG. 24 illustrates a cross section Y2 of the source/drain region of the second wiring scheme after removal of the first substrate, the etch stop, and the second substrate, and the formation of backside interlayer dielectric layer, in accordance with the embodiment of the present invention.

FIG. 25 illustrates a cross section Y3 of the source/drain region of the third wiring after removal of the first substrate, the etch stop, and the second substrate, and the formation of backside interlayer dielectric layer, in accordance with the embodiment of the present invention.

FIG. 26 illustrates a cross section X of the nanosheet stacked FET after formation of the backside connections, in accordance with the embodiment of the present invention.

FIG. 27 illustrates a cross section Y1 of the source/drain region of the first wiring scheme after formation of the backside connections, in accordance with the embodiment of the present invention.

FIG. 28 illustrates a cross section Y2 of the source/drain region of the second wiring scheme after formation of the backside connections, in accordance with the embodiment of the present invention.

FIG. 29 illustrates a cross section Y3 of the source/drain region of the third wiring after formation of the backside connections, in accordance with the embodiment of the present invention.

FIG. 30 illustrates a cross section X of the nanosheet stacked FET after recessing the first and second backside connections and formation of the backside cap, in accordance with the embodiment of the present invention.

FIG. 31 illustrates a cross section Y1 of the source/drain region of the first wiring scheme after recessing the first and second backside connections and formation of the backside cap, in accordance with the embodiment of the present invention.

FIG. 32 illustrates a cross section Y2 of the source/drain region of the second wiring scheme after recessing the first and second backside connections and formation of the backside cap, in accordance with the embodiment of the present invention.

FIG. 33 illustrates a cross section Y3 of the source/drain region of the third wiring after recessing the first and second backside connections and formation of the backside cap, in accordance with the embodiment of the present invention.

FIG. 34 illustrates a cross section X of the nanosheet stacked FET after formation of a backside-power-distribution-network, in accordance with the embodiment of the present invention.

FIGS. 35A and 35B illustrate a cross section Y1 of the source/drain region of the first wiring scheme after formation of a backside-power-distribution-network, in accordance with the embodiment of the present invention.

FIGS. 36A and 36B illustrate a cross section Y2 of the source/drain region of the second wiring scheme after formation of a backside-power-distribution-network, in accordance with the embodiment of the present invention.

FIG. 37 illustrates a cross section Y3 of the source/drain region of the third wiring after formation of a backside-power-distribution-network, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards stacked field-effect-transistors (stacked FET), specifically the present invention is directed towards different types of wiring schemes for stacked FET. The present invention will illustrate three different types of wiring schemes for stacked FET, where the first wiring scheme will connect the backside surface of the backside source/drain to a frontside interconnect layer. The first wiring scheme will include a connection via that extends through the backside source/drain such that a portion of the connection via is surrounded by the backside source/drain. The connection via is connected to a horizontal extension that is in contact with a backside surface of the backside source/drain. A second wiring scheme is similar to the first wiring scheme, except that frontside source/drain is connected to the connection via along with the backside source/drain.

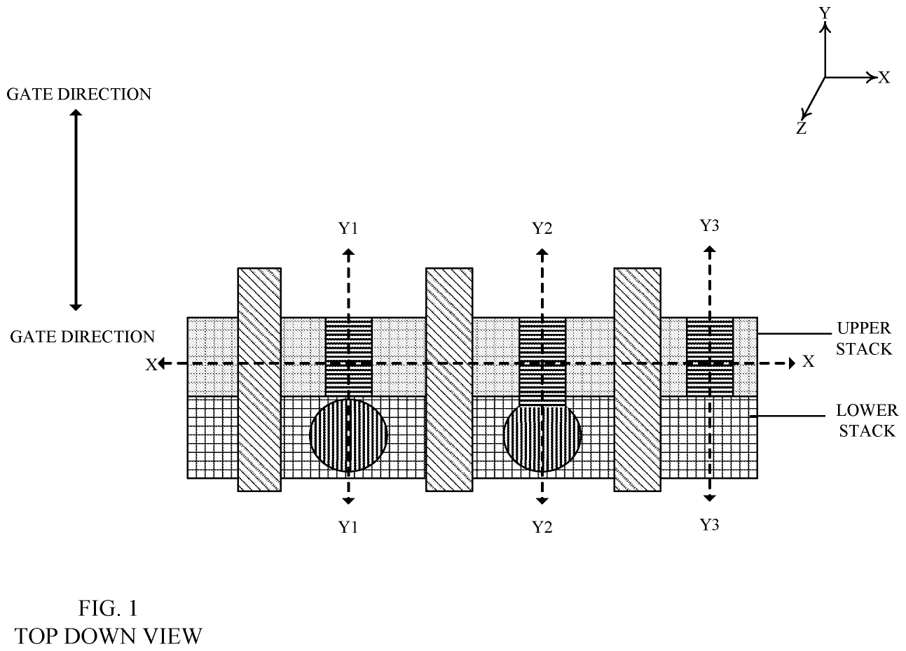

FIG. 1 illustrates a top-down view of multiple devices, in accordance with the embodiment of the present invention. The cross-section X extends horizontally through nanosheet transistors. Cross section Y1 is perpendicular to cross section X, where cross section Y1 is through a source/drain region that spans across multiple adjacent nanosheet transistors. Cross-section Y1 illustrates the first wiring scheme. Cross section Y2 is perpendicular to cross section X, where cross section Y2 is through a source/drain region that spans across multiple adjacent nanosheet transistors. Cross-section Y2 illustrates the second wiring scheme. Cross section Y3 is perpendicular to cross section X, where cross section Y3 is through a source/drain region that spans across multiple adjacent nanosheet transistors. Cross-section Y3 illustrates the third wiring scheme. Cross-section X is perpendicular to the gate direction and cross-section Y1, Y2, and Y3 are parallel to the gate direction.

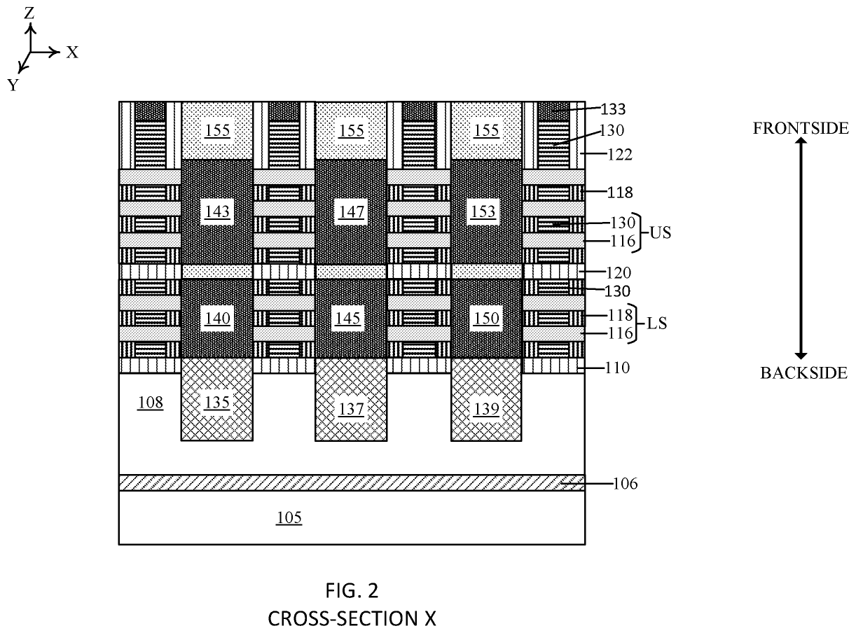

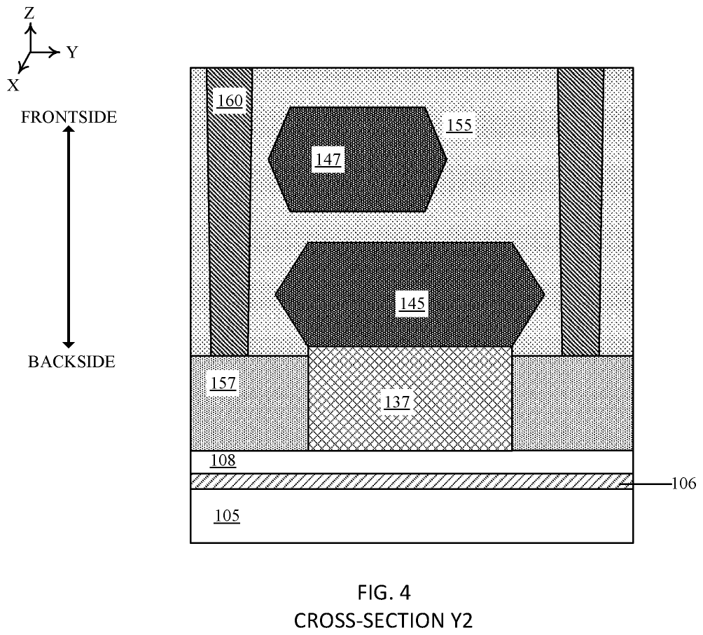

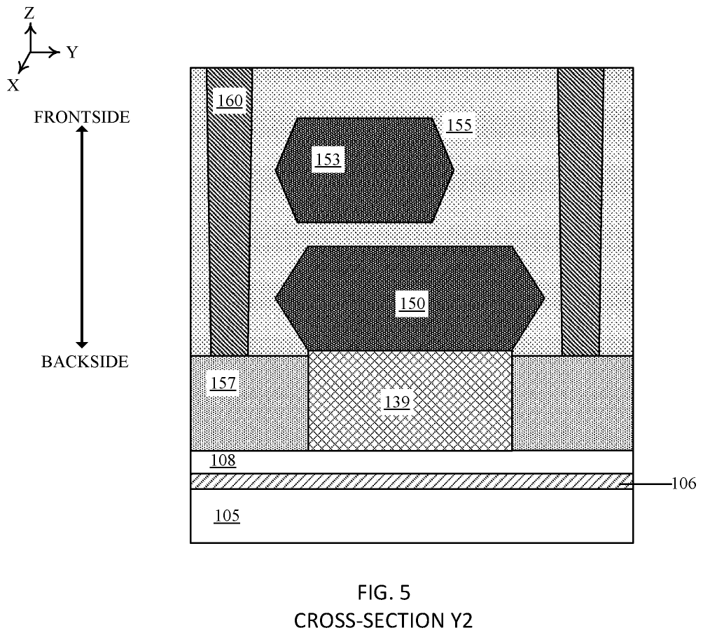

Referring now to FIGS. 2, 3, 4, and 5, a structure is shown during an intermediate step of a method of fabricating stacked nano devices, such as, a stacked nanosheet transistor structure after initial processing of the frontside of the stacked FET, according to an embodiment of the invention.

FIGS. 2, 3, 4, and 5 illustrate the processing stage after initial processing the frontside of the stacked FET.

FIG. 2 illustrates the nano stack of the nanosheet transistors that includes a first substrate 105, an etch stop 106, a second substrate 108, placeholders 135, 137, 139, bottom dielectric isolation layer 110, lower stack LS or backside stack, channel layers 116, inner spacer 118, gate 130, middle dielectric isolation layer 120, interlayer dielectric layer 155, gate spacer 122, gate cap 133, lower source/drain 140, 145, 150 (herein after also referred to as backside source/drain), and upper source/drain 143, 147, 153 (herein after also referred to as frontside source/drains).

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein. The plurality of channel layers 115 can be comprised of, for example, Si.

The lower source/drains (backside source/drains) 140, 145, 150 and the upper source/drains (frontside source/drains) 143, 147, 153 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. Gate 130 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

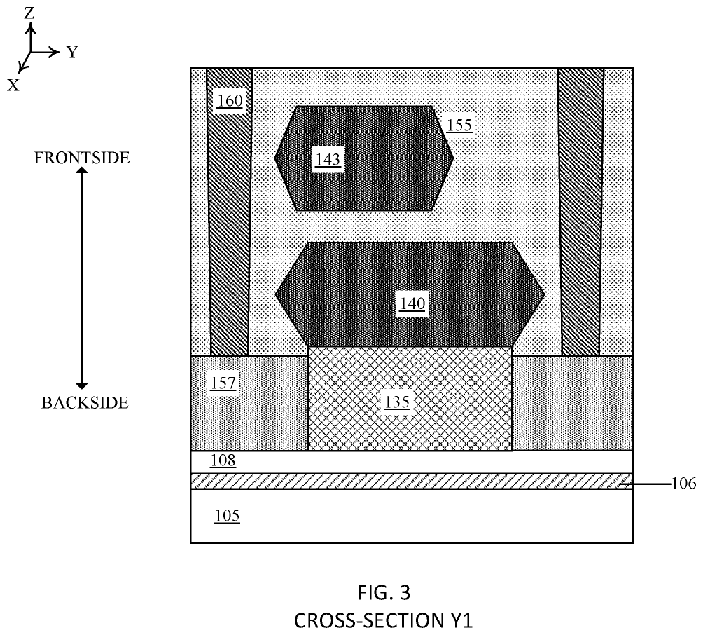

FIGS. 3, 4, and 5 further illustrate the shallow trench isolation layer 157 and the dielectric pillars 160. The backside source/drains 140, 145, 150 have a width that is larger than the frontside source/drain 143, 147, 153 as measured through the source/drain region (i.e., Y direction as indicated).

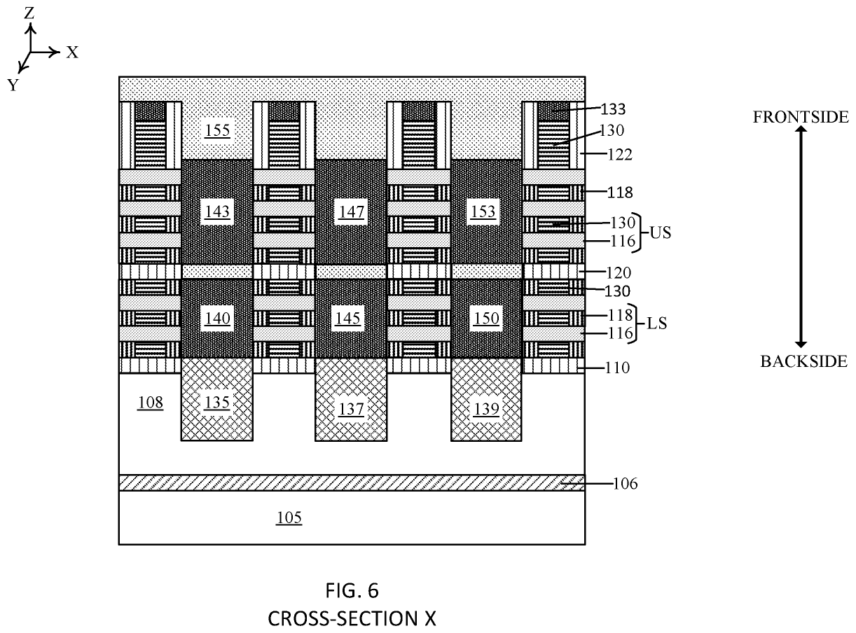

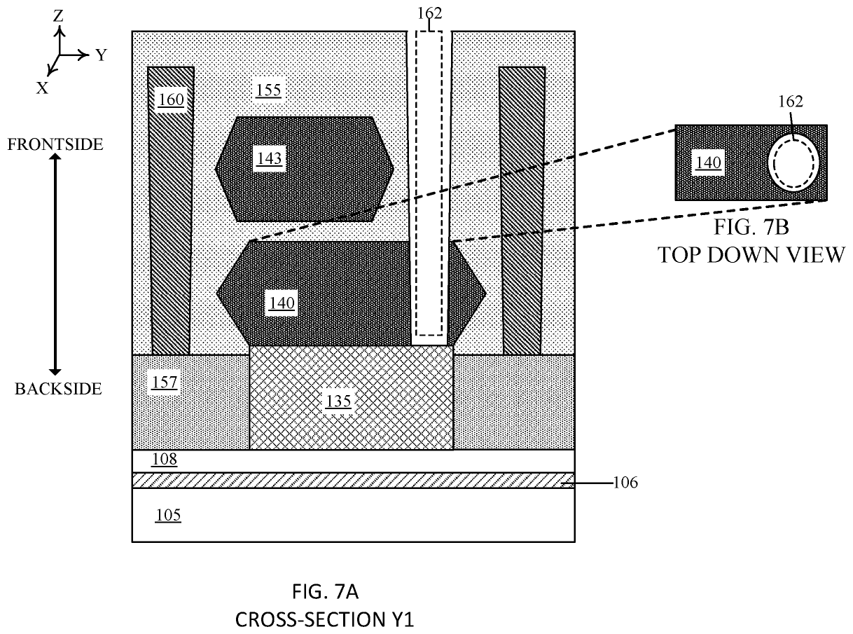

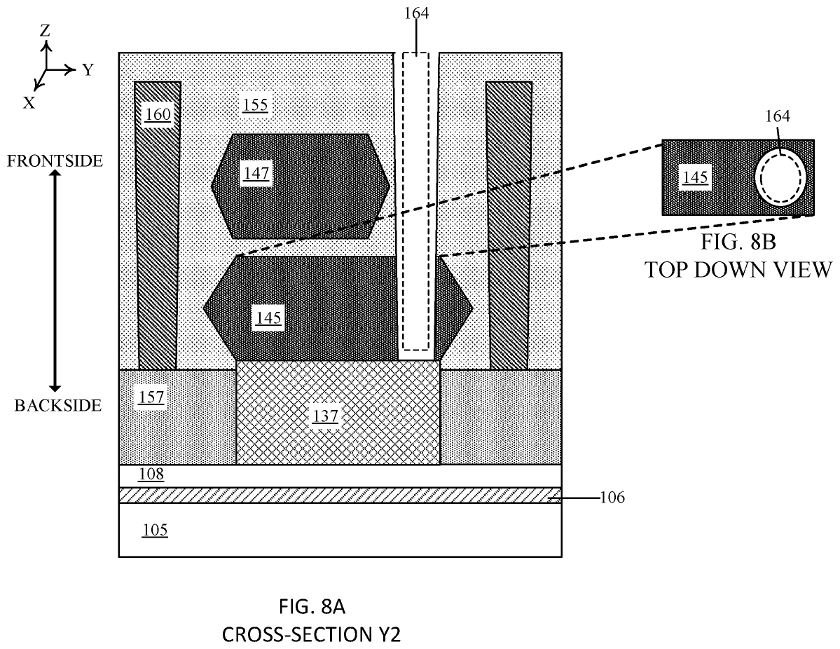

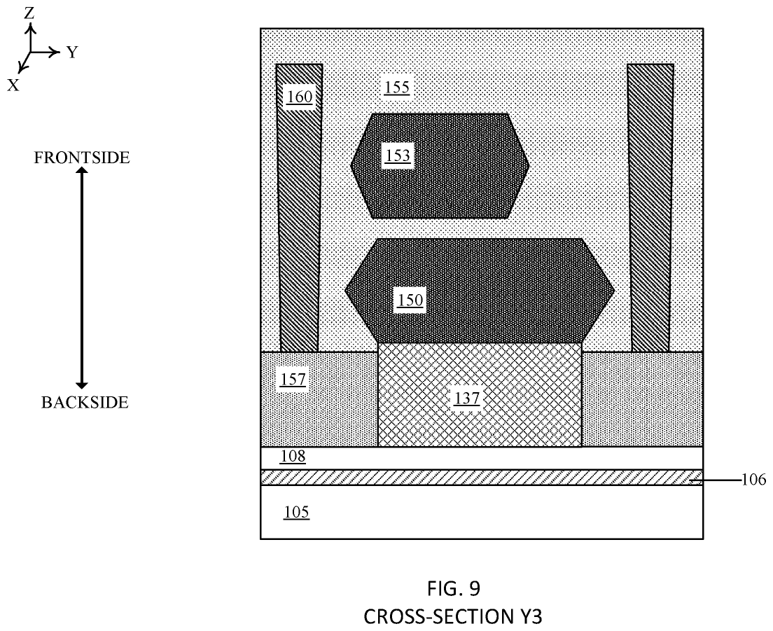

FIGS. 6, 7A, 7B, 8A, 8B, and 9 illustrate the processing stage after formation of a first and second connection via trench 162, 164. The height of the interlayer dielectric layer 155 is increased to extend the interlayer dielectric layer 155 on top of the gate caps 133 and on top of the dielectric pillars 160. A lithography layer (not shown) is formed on top of the interlayer dielectric layer 155. The lithography layer and the underlying layers are patterned to form the first and second connection via trenches 162, 164. The lithography layer is removed to expose the interlayer dielectric layer 155. FIGS. 7A and 7B illustrate the first connection via trench 162. The first connection via trench 162 extends downwards through the interlayer dielectric layer 155 and through the backside source/drain 140. The first connection via trench 162 exposes a top surface of the placeholder 135. FIG. 7B illustrates a top-down view of a top surface also referred to as a frontside surface of the backside source/drain 140 (or the lower source/drain 140). The first connection via trench 162 creates a hole/tunnel/passageway through the backside source/drain 140 without dividing the backside source/drain 140 into independent/separate pieces. This means that the backside source/drain 140 completely laterally surrounds the first connection via trench 162 as it passes through the backside source/drain 140. FIGS. 8A and 8B illustrate the same structure for the second connection via trench 164 as described above for the first connection via trench 162, such that the second connection via trench 164 passes through the backside source/drain 145 to expose a top surface of placeholder 137. The third wiring scheme as illustrated in FIG. 9 does not include a connection via trench.

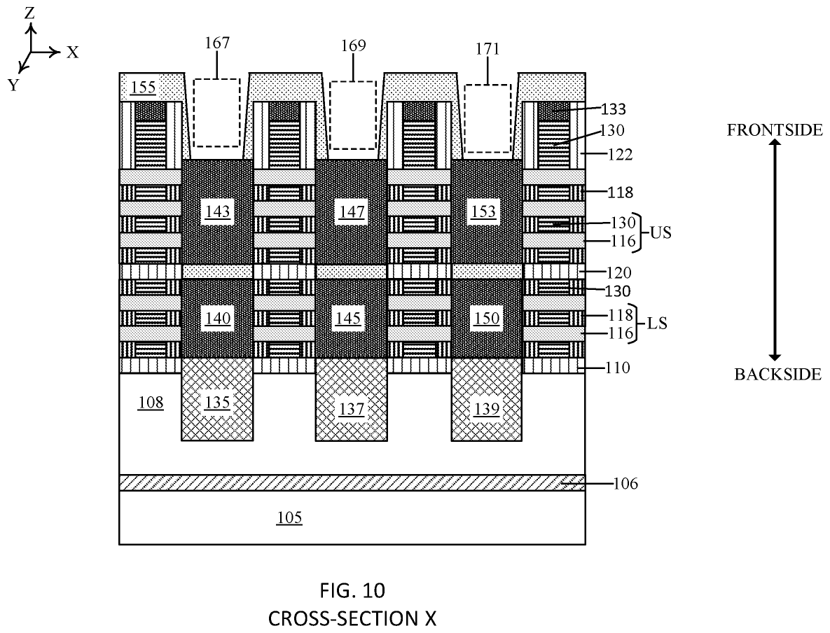

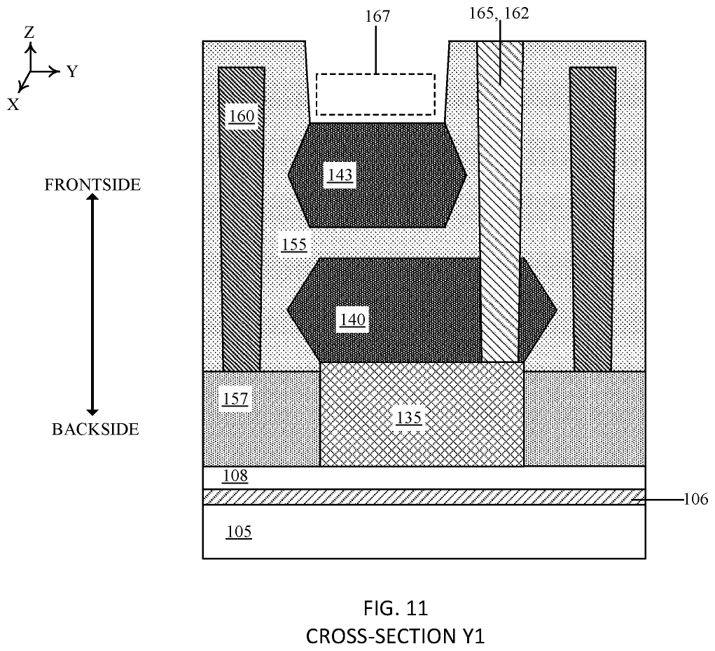

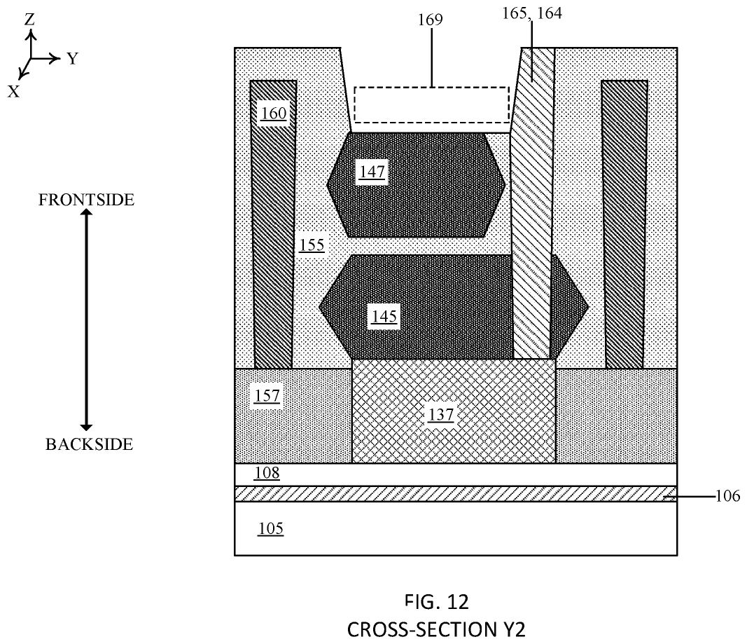

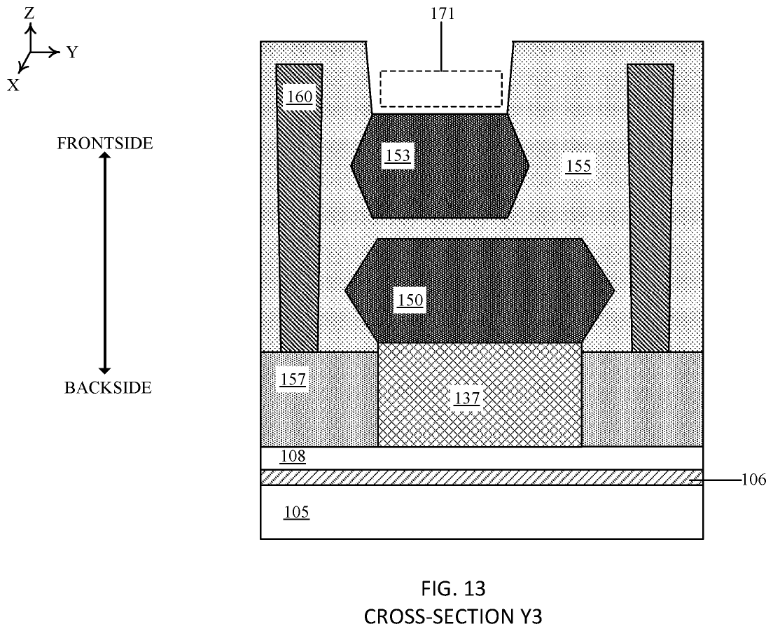

FIGS. 10, 11, 12, and 13 illustrate the processing stage after formation of the frontside source/drain contact trenches 167, 169, 171. A lithography layer 165 is formed on top of the interlayer dielectric layer 155 and the lithography layer 165 fills the first and second connection via trenches 162, 164. The lithography layer 165 and the interlayer dielectric layer 155 are patterned to form a plurality of frontside source/drain contact trenches 167, 169, 171. The lithography layer 165 will be completely removed, however FIGS. 10-13 illustrate the stage of processing that is prior to the complete lithography layer 165 removal. For example, FIGS. 10-13 illustrate a portion of the lithography layer 165 being still located within the first and second connection via trench 162, 164. FIG. 10 illustrates the plurality of frontside source/drain contact trenches 167, 169, 171 expose a top surface of a frontside source/drain 143, 147, 153, respectively. FIG. 11 illustrates the first wiring scheme where the first frontside source/drain contact trench 167 exposes the top surface of the frontside source/drain 143. The first frontside source/drain contact trench 167 does not connect to the first connection via trench 162, such that, a portion of the interlayer dielectric layer 155 is located between the first frontside source/drain contact trench 167 and the first connection via trench 162. FIG. 12 illustrates the second wiring scheme where the second frontside source/drain contact trench 169 exposes a top surface of the frontside source/drain 147. Furthermore, the second frontside source/drain contact trench 169 exposes the second connection via trench 164. This means that the second frontside source/drain contact trench 169 extends laterally into the second connection via trench 164, thus connecting the two trenches (once the lithography layer 165 is removed). FIG. 13 illustrates the third wiring scheme where the third frontside source/drain contact trench 171 exposes a top surface (frontside surface) of the frontside source/drain 153.

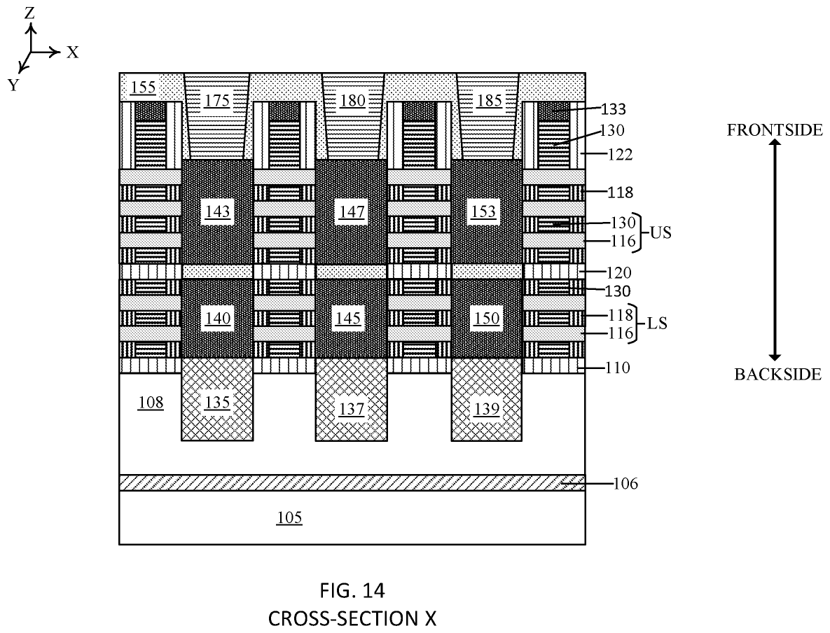

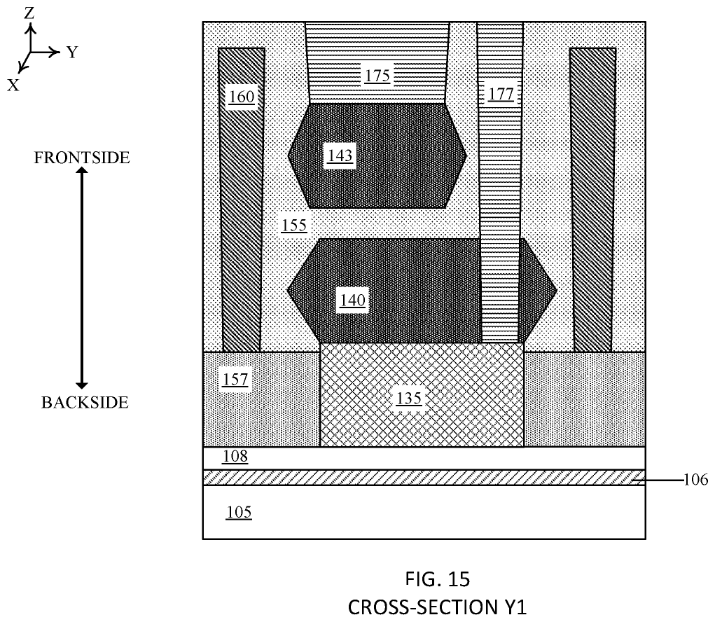

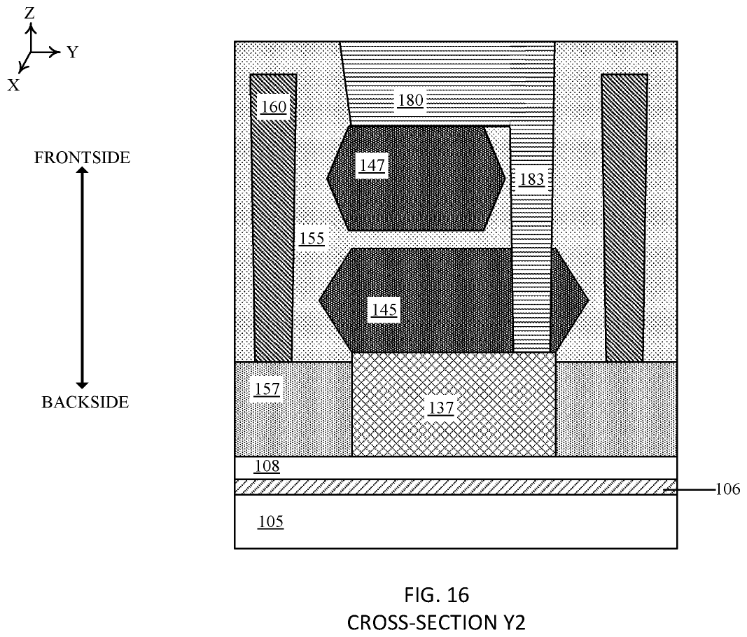

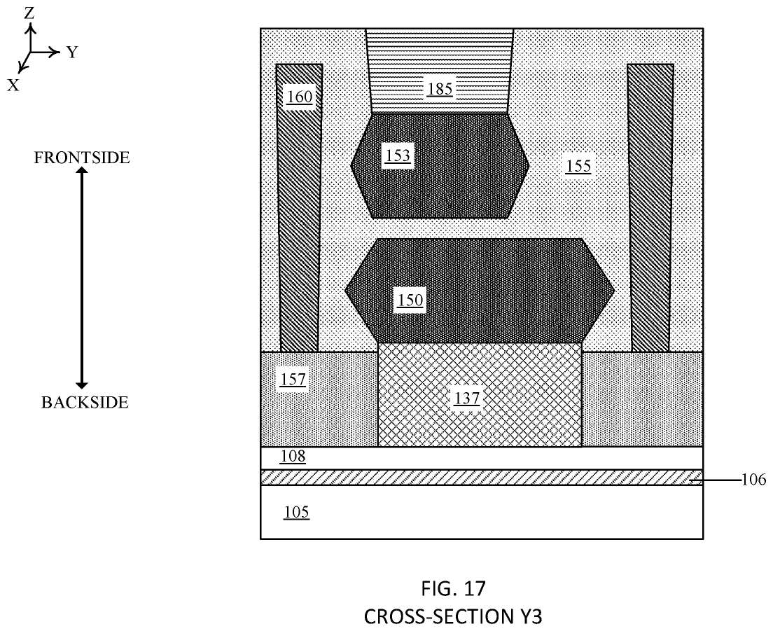

FIGS. 14, 15, 16, and 17 illustrate the processing stage after formation of the frontside source/drain contacts 175, 180, 185 and the formation of the connection vias 177, 183. The lithograph layer 165 is removal is finished which exposes the first and second connection via trenches 162, 164. Frontside source/drain contacts 175, 180, 185 and the connection vias 177, 183 are formed by filling the frontside source/drain contact trenches 167, 169, 171 and the connection via trenches 162, 164 with a conductive metal. FIG. 15 illustrates the first wiring scheme where the first frontside source/drain contact 175 is in contact with frontside source/drain 143. The first connection via 177 passes through the backside source/drain 140 and is in contact with placeholder 135. The first frontside source/drain contact 175 and the first connection via 177 are not in direct contact, where the interlayer dielectric layer 155 laterally isolates the frontside source/drain contact 175 from the first connection via 177. FIG. 16 illustrates the second wiring scheme, where the second frontside source/drain contact 180 is formed integrally with the second connection via 183. The integrally formation of these two contacts (e.g., the frontside source/drain contact 180 and the second connection via 183) is achievable because the second frontside contact trench 169 was laterally connected to the second connection via trench 164. Therefore, the combination of the second frontside source/drain contact 180 and the second connection via 183 is in contact with the frontside source/drain 147 and the backside source/drain 145. The second connection via 183 passes through the backside source/drain 145 to contact placeholder 137. FIG. 17 illustrates the third wiring scheme where the third frontside source/drain contact 185 is in contact with the frontside source/drain 147.

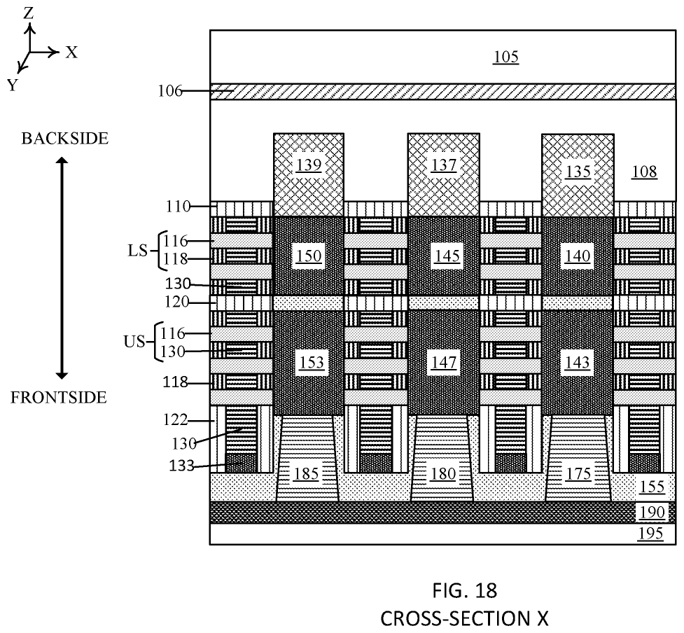

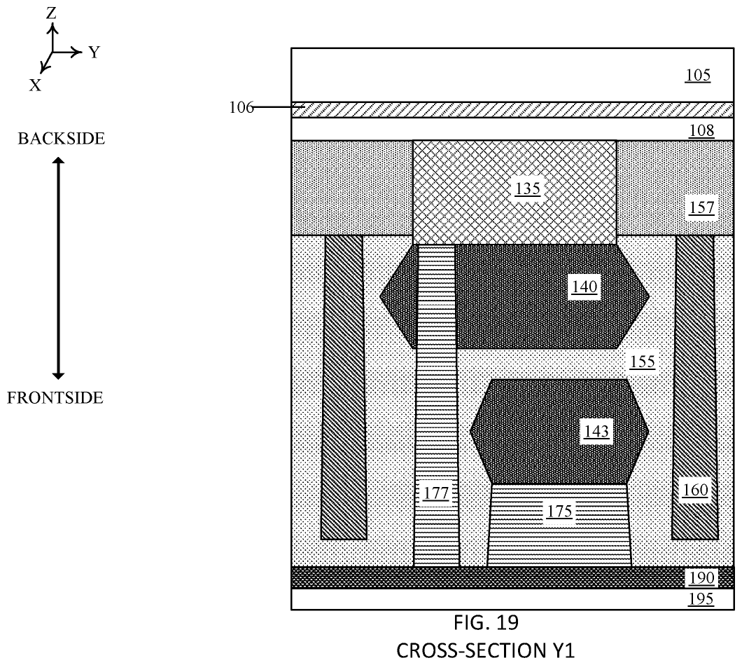

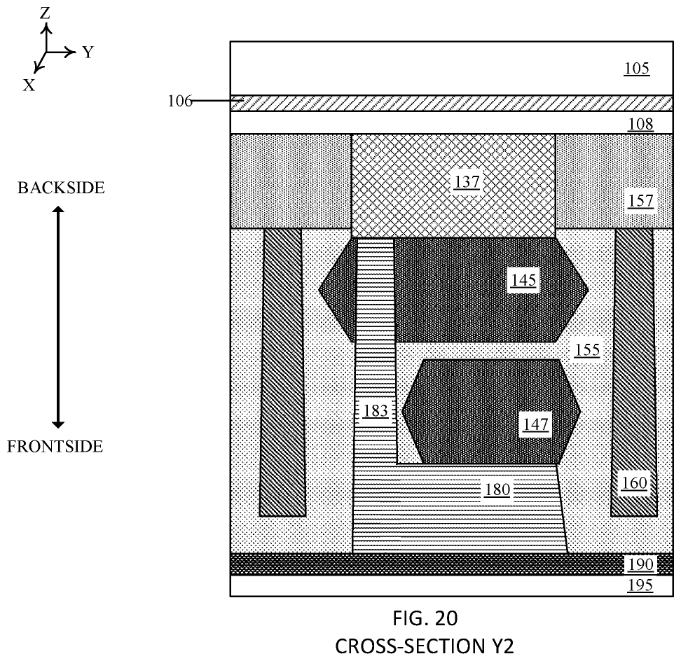

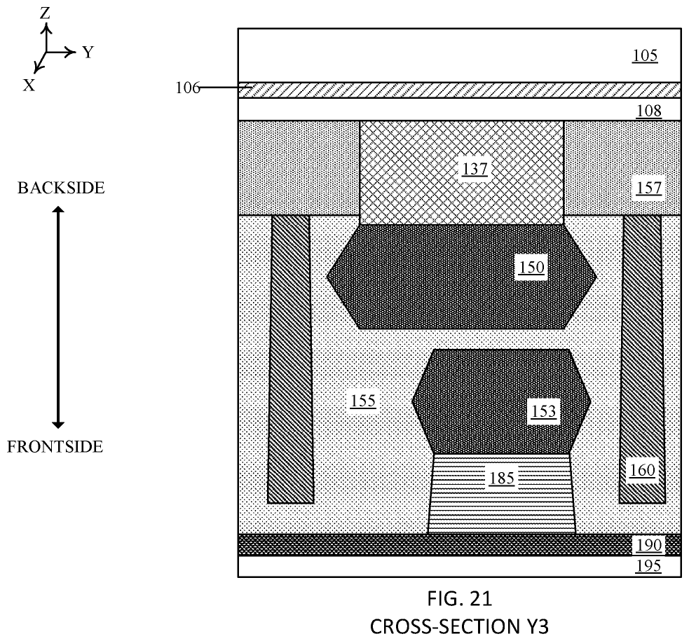

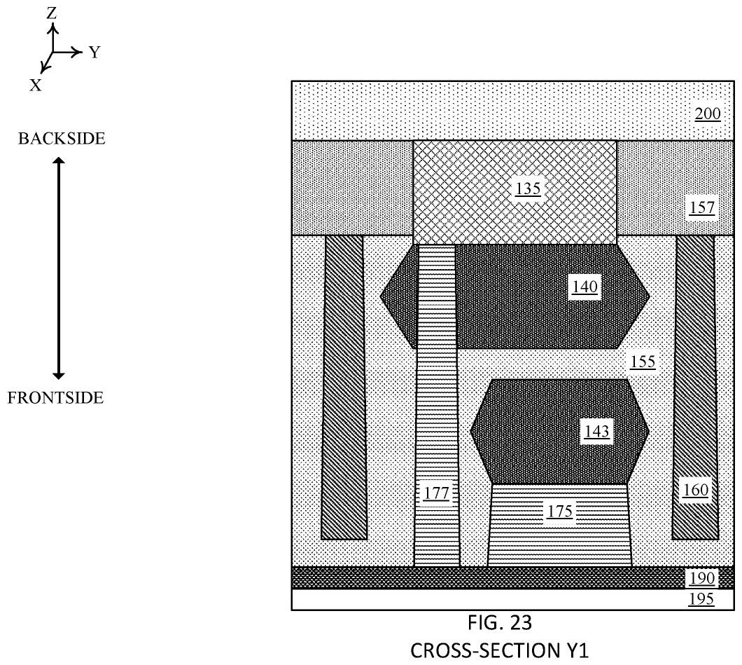

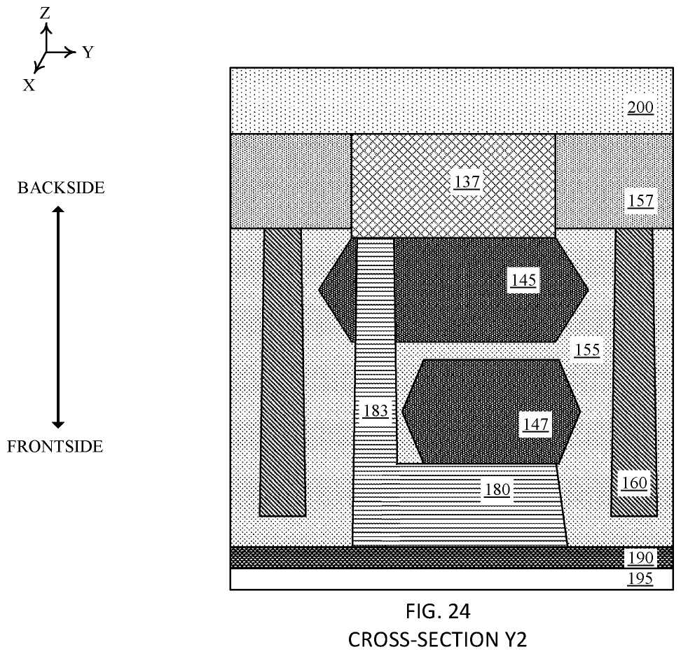

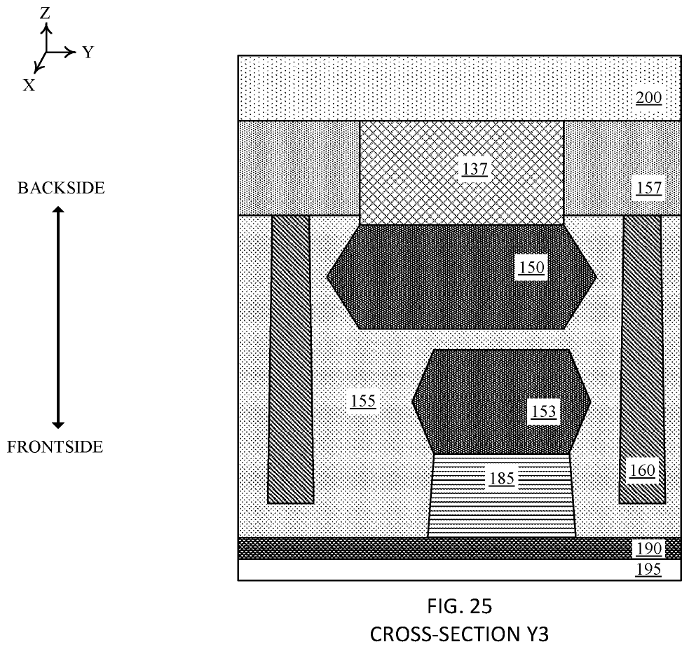

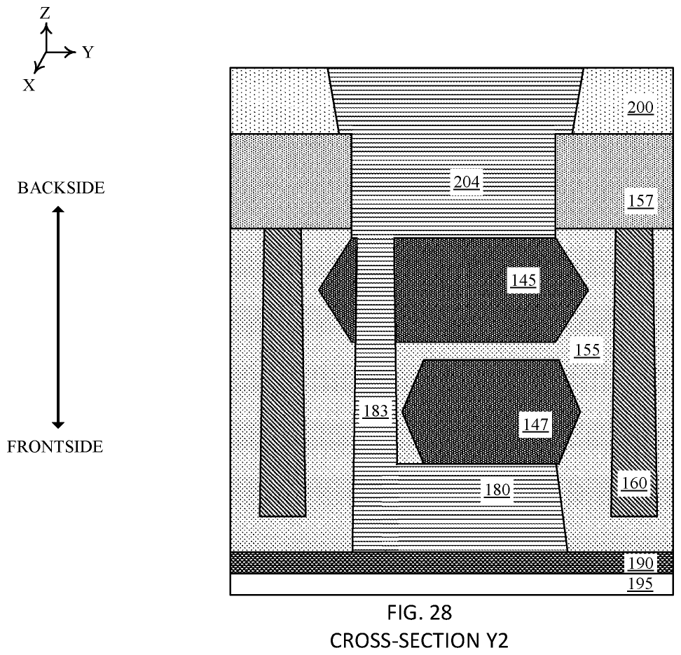

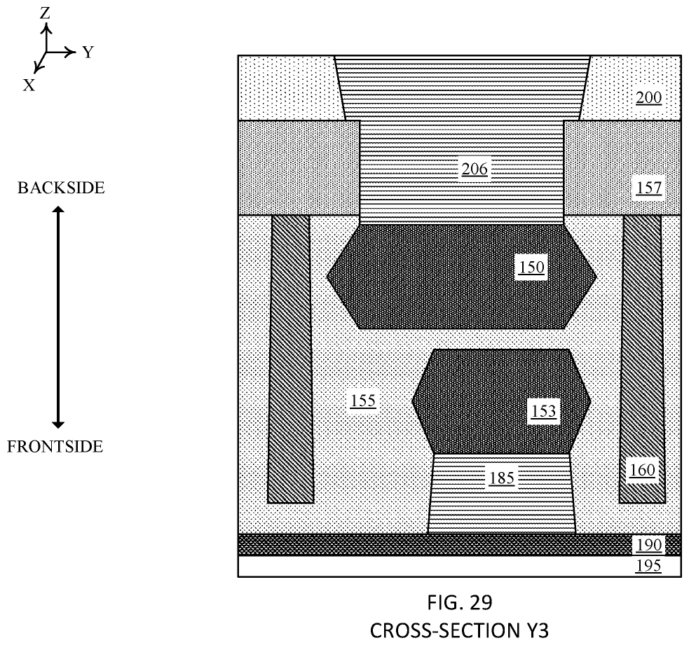

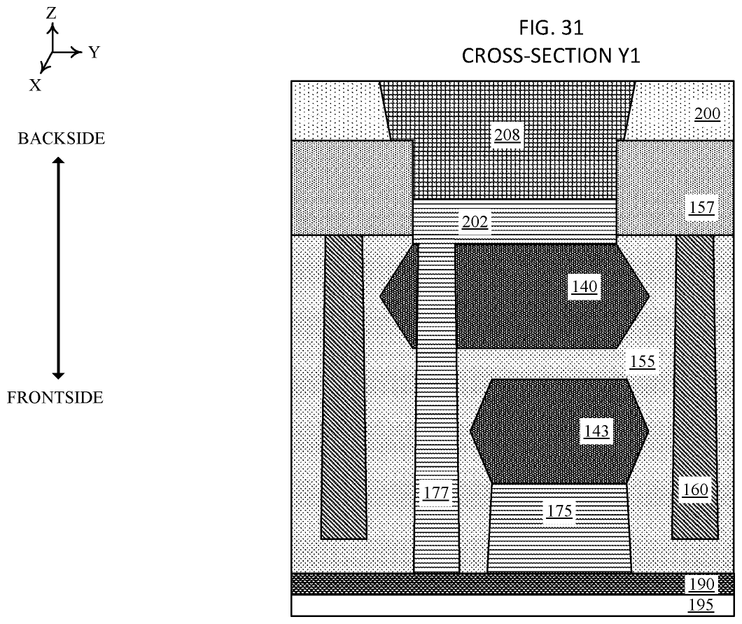

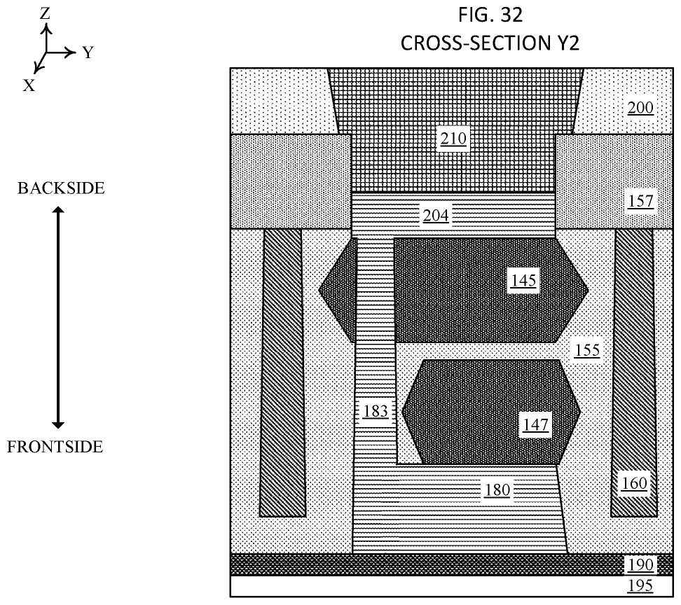

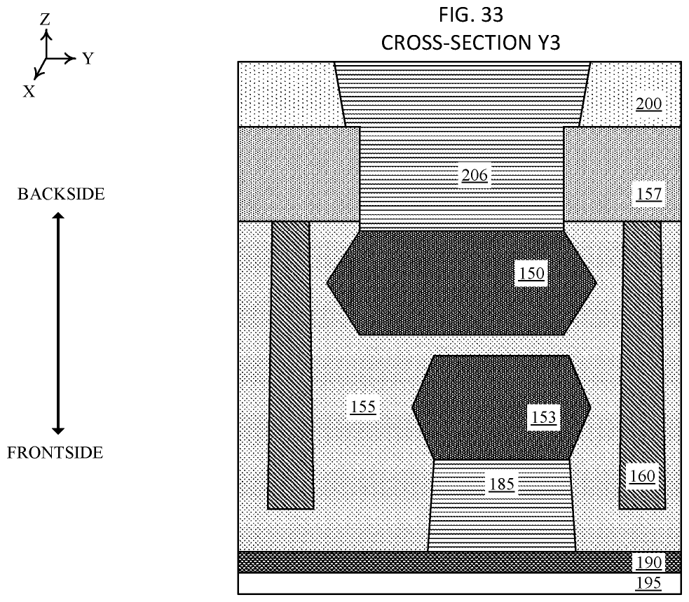

FIGS. 18, 19, 20, and 21 illustrate the processing stage after formation of the back-end-of-the-line (BEOL) layer 190 and the carrier wafer 195, and flipping the nanosheet stacked FET over for backside processing. The BEOL layer 190 is formed on top of the frontside interlayer dielectric layer 155 and on top of the frontside source/drain contacts 175, 180, 185 and on top of the connection vias 177, 183. The BEOL layer 190 can be comprised of multiple layers and connections to make the electrical connections to the frontside source/drain contacts 175, 180, 185 and the connection vias 177, 183. Carrier wafer 195 is formed on top of the BEOL layer 190. The carrier wafer 195 allows for the stacked nanosheet FET to be flipped over for backside processing as illustrated in FIGS. 18-37. FIGS. 2-17 illustrated the frontside processing of the stacked nanosheet FET.

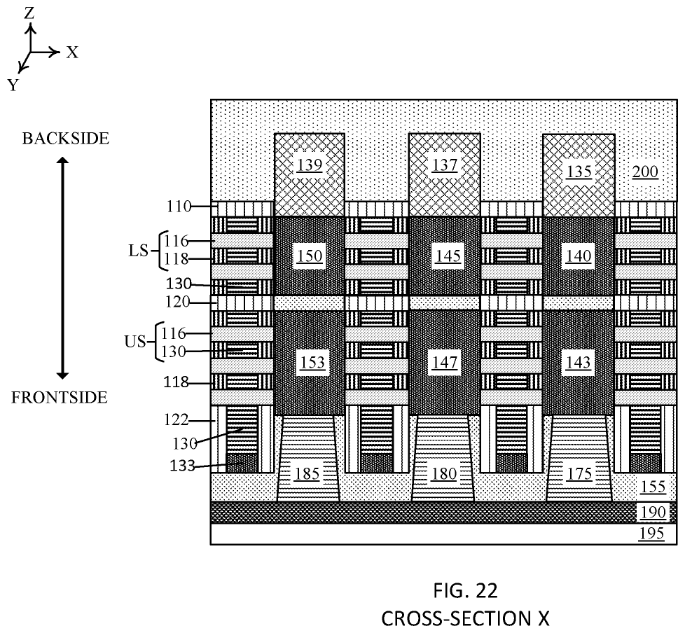

FIGS. 22, 23, 24, and 25 illustrate the processing stage after removal of the first substrate 105, the etch stop 106, and the second substrate 108, and the formation of backside interlayer dielectric layer 200. The first substrate 105, the etch stop 106, and the second substrate 108 are removed by a suitable etching/planarization process. The removal of these layers exposes a backside surface of placeholders 135, 137, 139 that are located on the backside surface of the backside source/drains 140, 145, 150. The removal of these layers also exposes a backside surface of the bottom dielectric isolation layer 110 and a backside surface of the shallow trench isolation layer 157. A bottom interlayer dielectric layer 200 is formed on top of these exposed layers such that the bottom interlayer dielectric layer 200 surrounds the exposed surfaces of placeholders 135, 137, 139 as illustrated in FIG. 22.

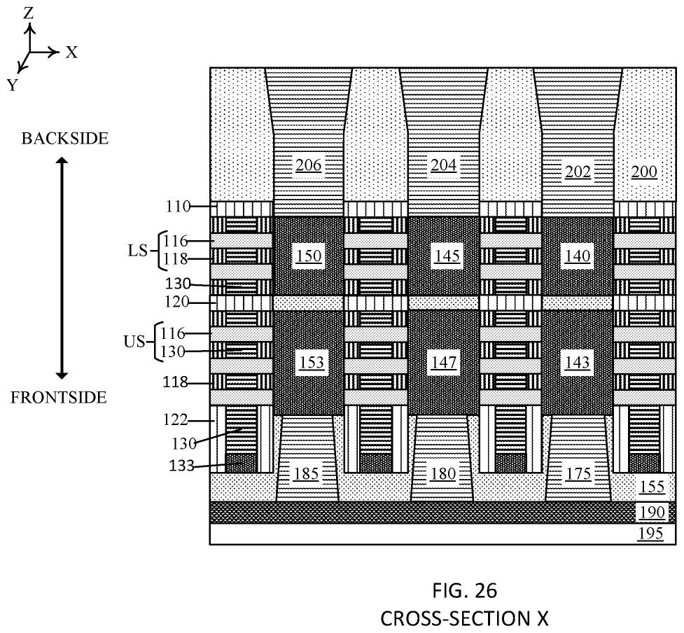

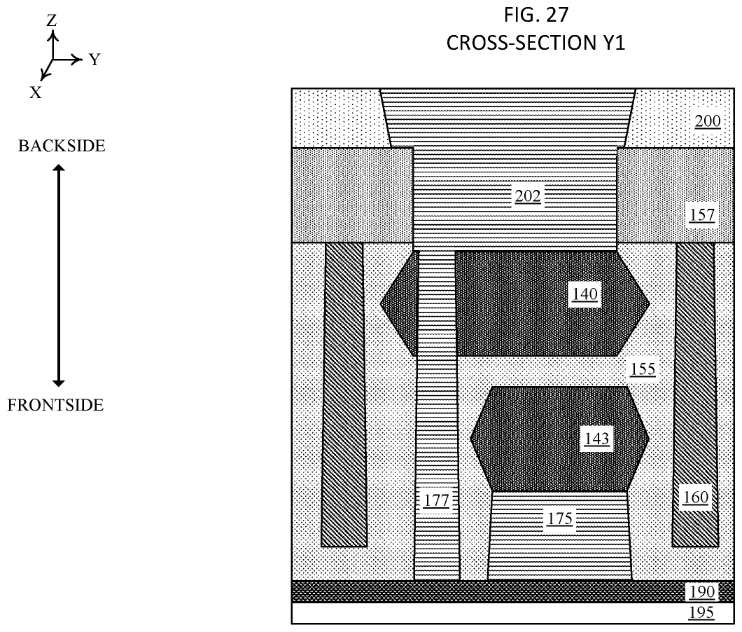

FIGS. 26, 27, 28, and 29 illustrate the processing stage after formation of the backside connections 202, 204, 206. A lithography layer (not shown) is formed on top of the backside interlayer dielectric layer 200. The lithography layer and the backside interlayer dielectric layer 200 are patterned to form a plurality of trenches (not shown) that expose the backside surface of placeholders 135, 137, 139. The lithography layer and the placeholders 135, 137, 139 are removed which creates trenches (not shown) within the backside interlayer dielectric layer 200 and the shallow trench isolation layer 157, such that the backside surface of the backside source/drains 140, 145, 150 are exposed. Furthermore, the backside surface of the connection vias 177, 183 are exposed by the trenches (not shown). Backside connections 202, 204, 206 are formed by filling these trenches (not shown) with a conductive metal. The backside connections 202, 204, 206 are in contact with the backside surfaces of the backside source/drains 140, 145, 150, respectively. The first backside connection 202 is in contact with the backside surface of the first connection via 177 as illustrated in FIG. 27. The first backside connection 202 extends laterally along the backside surface of the backside source/drain 140. The second backside connection 204 is in contact with a backside surface of the second connection via 183, thus a shared contact is formed. The shared contact includes the second frontside contact 180, the second connection via 183, and the second backside connection 204, such that the frontside source/drain 147 and the backside source/drain 145 are connected to the shared contact. The second backside connection 204 extends laterally along the backside surface of the backside source/drain 145. The third backside connection 206 (or backside contact 206) is connected to the backside surface of the third backside source/drain 150.

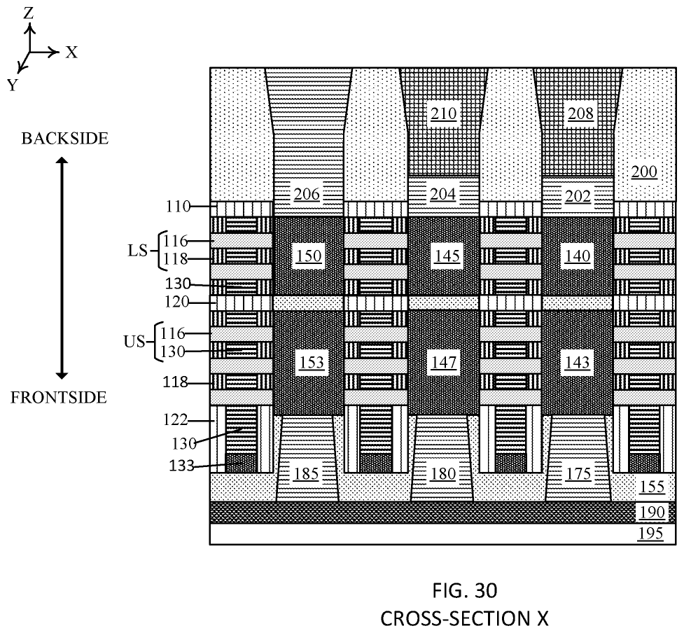

FIGS. 30, 31, 32, and 33 illustrate the processing stage after recessing the first and second backside connections 202, 204 and formation of the backside cap 208, 210. A lithography layer (not shown) is formed on top of the backside interlayer dielectric layer 200 and on top of the backside connections 202, 204, 206. The lithography layer is patterned to expose the first and second backside connections 202, 204. The third backside connection 206, herein after referred to as the backside contact 206, is protected by the lithography layer. The first and second backside connections 202, 204 are recessed or pulled down, thus decreasing the height of these components. The first and second backside connections 202, 204 are not completely removed, meaning that a portion of each of the backside connections 202, 204 remains in contact with the backside surface of the backside source/drains 140, 145. The first and second backside connections 202, 204 increases the surface area of contact between the backside source/drains 140 and 145 and each of their corresponding contacts, which will be described in further detail below. Backside caps 208 and 210 are formed on top of the first and second backside connection 202, 204, respectively. The lithography layer and any excess backside cap 208, 210 material is removed.

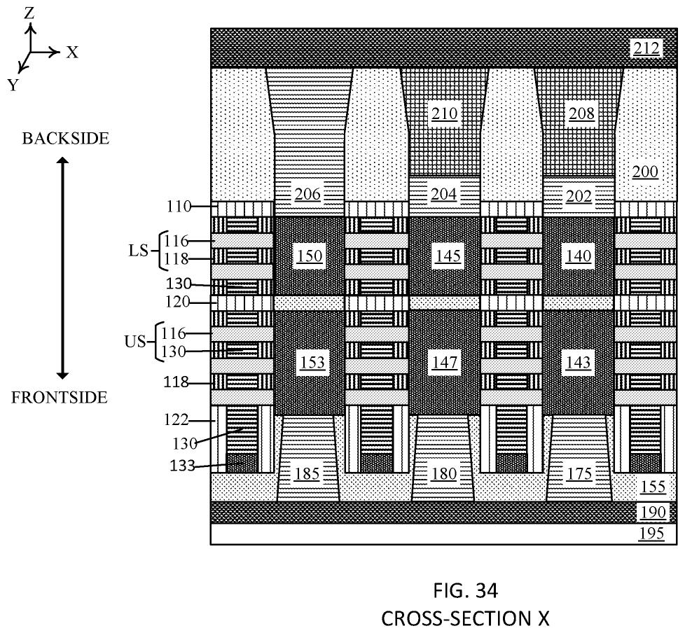

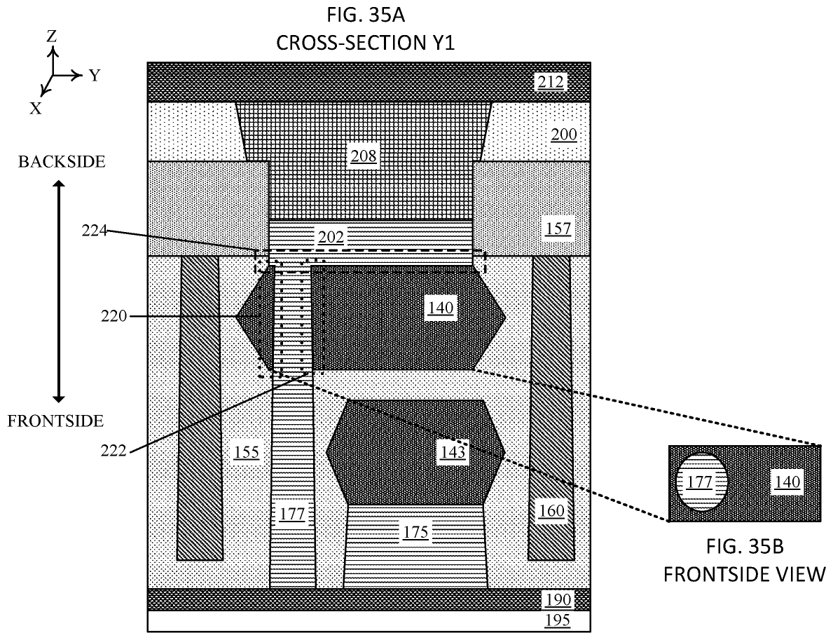

FIGS. 34, 35A, 35B, 36A, 36B, and 37 illustrate the processing stage after formation of a backside-power-distribution-network (BSPDN) 212. BSPDN 212 is formed on top of the backside dielectric layer 200, on the backside caps 208, 210, and on top of the backside contact 206. Backside caps 208, 210 prevent the BSPDN 212 from connecting to the backside connections 202, 204. FIGS. 35A and 35B illustrate the first wiring scheme that includes a frontside contact 175, a frontside source/drain 143, a first connection via 177, a backside source/drain 140, and a backside connection 202. The frontside contact 175 is independent (i.e., separate) from the first connection via 177. FIG. 35B illustrates a view of the frontside surface of the backside source/drain 140. The backside source/drain 140 surrounds the first connection via 177 as it passes through it. The backside source/drain 140 is in contact with the sides of the first connection via 177, as emphasized by dashed boxes 220, 222. FIG. 35B illustrates that the first connection via 177 has a circular profile. The shown profile of the first connection via 177 is for exemplary purposes only. Dashed boxes 220, 222 emphasize that the surface area of the contact between the backside source/drain 140 and the sidewalls of the first connection via 177. Dash box 224 illustrates that the lateral surface area or contact area between the backside connection 202 and the backside surface of the backside source/drain 140. A combined contact surface area (i.e., dashed boxes 220, 222, and 224) is equal to the surface area of contact between the backside source/drain and the first connection via 177, and backside connection 202.

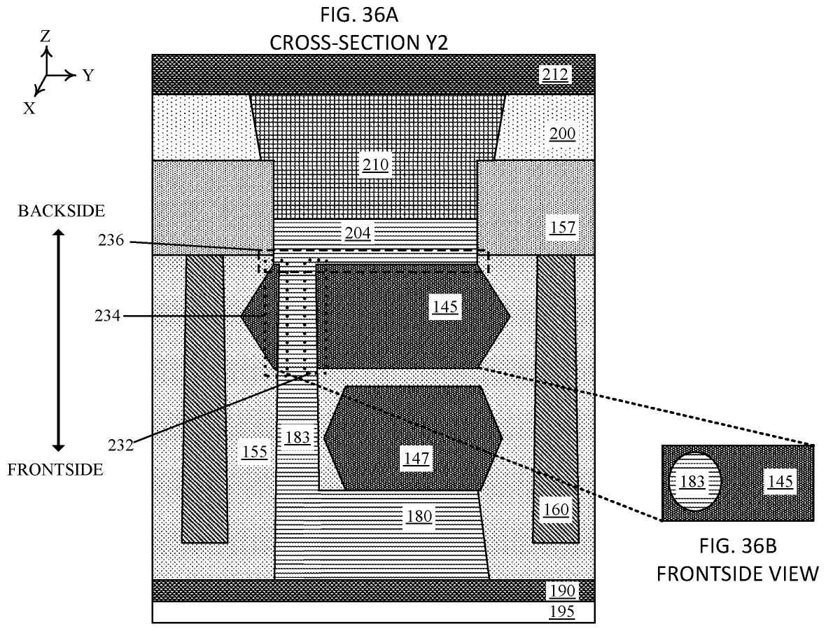

FIGS. 36A and 36B illustrate the second wiring scheme that includes a frontside contact 180, a frontside source/drain 147, a second connection via 183, a backside source/drain 145, and a backside connection 204. The frontside contact 180 is formed integrally with the second connection via 183. The frontside contact 180, the second connection via 183, and the backside connection 204 forms a singular/shared contact that connects to the frontside source/drain 147 and the backside source/drain 145. FIG. 36B illustrates a view of the frontside surface of the backside source/drain 145. The backside source/drain 145 surrounds the second connection via 183 as it passes through it. The backside source/drain 145 is in contact with the sides of the second connection via 183, as emphasized by dashed boxes 232, 234. FIG. 36B illustrates that the second connection via 183 has a circular profile. The shown profile of the second connection via 183 is for exemplary purposes only. Dashed boxes 232, 234 emphasize that the surface area of the contact between the backside source/drain 145 and the sidewalls of the second connection via 183. Dash box 236 illustrates that the lateral surface area or contact area between the backside connection 204 and the backside surface of the backside source/drain 145. A combined contact surface area (i.e., dashed boxes 232, 234, and 236) is equal to the surface area of contact between the backside source/drain and the second connection via 183, and backside connection 204.

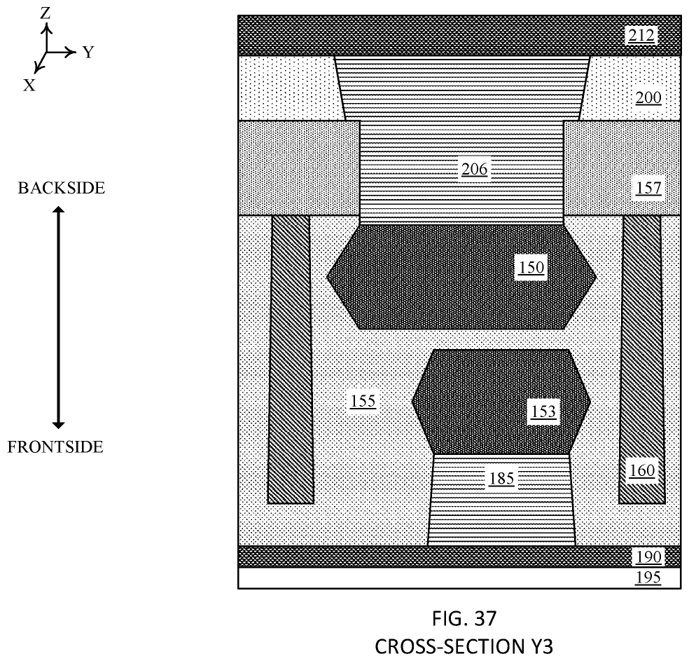

FIG. 37 illustrates the third wiring scheme that includes a frontside contact 185, a frontside source/drain 147, a backside source/drain 150, and a backside contact 206. The frontside contact 185 and the backside contact 206 are independent from each other. Furthermore, the third wiring scheme does not include a connection via that passes through the backside source/drain 150.

A microelectronic structure that includes a stacked FET that includes a frontside source/drain 143, 147, and a backside source/drain 140, 145. A connection via 177, 183 that passes through the backside source/drain 140, 145. The connection via 177, 183 extends from a frontside surface of the backside source/drain 140, 145 to a backside surface of the backside source/drain 140, 145. The backside source/drain 140, 145 surrounds the connection via 177, 183 as it passes through the backside source/drain 140, 145.

A backside connection 202, 204 located on the backside surface of the backside source/drain 140, 145. The backside connection 202, 204 extends laterally across the backside surface of the backside source/drain 140, 145. The backside connection 202, 204 is connected to the connection via 177, 183. A frontside contact 175, 180 connected to the frontside source/drain 143, 147.

The frontside contact 175 is independent of the connection via 177. A frontside interlayer dielectric layer 155 located between the connection via 177 and the frontside contact 175.

The frontside contact 180 extends laterally to connect with the connection via 183. The backside connection 204, the connection via 183, and the frontside contact 180 form a shared contact. The shared contact is in contact with a frontside surface of the frontside source/drain 147 and portions of a sidewall of the shared contact (183) are in contact with the backside source/drain 145, and the shared contact is in contact with a backside surface of the backside source/drain 145.

A microelectronic structure includes a stacked FET that includes a first frontside source/drain 143, a second frontside source/drain 147, a first backside source/drain 140, and a second backside source/drain 145. A first wiring scheme is utilized to make connections to the first frontside source/drain 143 and the first backside source/drain 140 and a second wiring scheme is utilized to make connections to the second frontside source/drain 147 and the second backside source/drain 145. The first wiring scheme and the second wiring scheme are different wiring schemes. The first wiring scheme includes a first connection via 177 that passes through the first backside source/drain 140. The first connection via 177 extends from a frontside surface of the first backside source/drain 140 to a backside surface of the first backside source/drain 140. The first backside source/drain 140 surrounds the first connection via 177 as it passes through the first backside source/drain 140.

The first wiring scheme further includes a first backside connection 202 located on the backside surface of the first backside source/drain 140. The first backside connection 202 extends laterally across the backside surface of the first backside source/drain 140. The first backside connection 202 is connected to the first connection via 177. A first frontside contact 175 connected to the first frontside source/drain 143. The first frontside contact 175 is independent of the connection via 177.

The second wiring scheme includes a second connection via 183 that passes through the second backside source/drain 145. The second connection via 183 extends from a frontside surface of the second backside source/drain 145 to a backside surface of the second backside source/drain 145. The second backside source/drain 145 surrounds the second connection via 183 as it passes through the second backside source/drain 145. A second backside connection 204 located on the backside surface of the second backside source/drain 140. The second backside connection 204 extends laterally across the backside surface of the second backside source/drain 140. A second frontside contact 180 connected to the second frontside source/drain 147. The second frontside contact 180 extends laterally to connect with the second connection via 183. The second backside connection 204, the second connection via 183, and the second frontside contact 180 form a shared contact. The shared contact is in contact with a frontside surface of the second frontside source/drain 147. Portions of a sidewall of the shared contact (183) are in contact with the second backside source/drain 145, and the shared contact is in contact with a backside surface of the second backside source/drain 145.

A first backside cap 208 located on the backside surface of the first backside connection 202. A second backside cap 210 located on the backside surface of the second backside connection 204.

A microelectronic structure includes a stacked FET that includes a first frontside source/drain 143, 147, a second frontside source/drain 153, a first backside source/drain 140, 145, and a second backside source/drain 150. A first wiring scheme is utilized to make connections to the first frontside source/drain 143, 147 and the first backside source/drain 140, 145 and a second wiring scheme is utilized to make connections to the second frontside source/drain 153 and the second backside source/drain 150. The first wiring scheme and the second wiring scheme are different wiring schemes. The first wiring scheme includes a connection via 177, 183 that passes through the first backside source/drain 140, 145. The connection via 177, 183 extends from a frontside surface of the first backside source/drain 140, 145 to a backside surface of the first backside source/drain 140, 145. The first backside source/drain 140, 145 surrounds the connection via 177, 183 as it passes through the first backside source/drain 140, 145. A backside connection 202, 204 located on the backside surface of the first backside source/drain 140, 145. The backside connection 202, 204 extends laterally across the backside surface of the first backside source/drain 140, 145. A backside cap 208, 210 located on the backside surface of a backside connection 202, 204. The second wiring scheme includes a backside contact 206 in contact with a backside side surface of the second backside source/drain 150. A backside power distribution network 215 is connected to the backside contact 206.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stacked FET that includes a frontside source/drain and a backside source/drain; and
a connection via that passes through the backside source/drain, wherein the connection via extends from a frontside surface of the backside source/drain to a backside surface of the backside source/drain, wherein the backside source/drain surrounds the connection via as it passes through the backside source/drain.

2. The microelectronic structure of claim 1, further comprising:
a backside connection located on the backside surface of the backside source/drain, wherein the backside connection extends laterally across the backside surface of the backside source/drain.

3. The microelectronic structure of claim 2, wherein the backside connection is connected to the connection via.

4. The microelectronic structure of claim 3, further comprising:
a frontside contact connected to the frontside source/drain.

5. The microelectronic structure of claim 4, wherein the frontside contact is independent of the connection via.

6. The microelectronic structure of claim 5, further comprising:
a frontside interlayer dielectric layer located between the connection via and the frontside contact.

7. The microelectronic structure of claim 4, wherein the frontside contact extends laterally to connect with the connection via.

8. The microelectronic structure of claim 7, wherein the backside connection, the connection via, and the frontside contact form a shared contact, wherein the shared contact is in contact with a frontside surface of the frontside source/drain, wherein portions of a sidewall of the shared contact are in contact with the backside source/drain, and wherein the shared contact is in contact with a backside surface of the backside source/drain.

9. A microelectronic structure comprising:
a stacked FET that includes a first frontside source/drain, a second frontside source/drain, a first backside source/drain, and a second backside source/drain;
a first wiring scheme is utilized to make connections to the first frontside source/drain and the first backside source/drain; and
a second wiring scheme is utilized to make connections to the second frontside source/drain and the second backside source/drain, wherein the first wiring scheme and the second wiring scheme are different wiring schemes;
wherein the first wiring scheme comprises;
a first connection via that passes through the first backside source/drain, wherein the first connection via extends from a frontside surface of the first backside source/drain to a backside surface of the first backside source/drain, wherein the first backside source/drain surrounds the first connection via as it passes through the first backside source/drain.

10. The microelectronic structure of claim 9, wherein the first wiring scheme further comprises:
a first backside connection located on the backside surface of the first backside source/drain, wherein the first backside connection extends laterally across the backside surface of the first backside source/drain.

11. The microelectronic structure of claim 10, wherein the first backside connection is connected to the first connection via.

12. The microelectronic structure of claim 11, further comprising:
a first frontside contact connected to the first frontside source/drain.

13. The microelectronic structure of claim 12, wherein the first frontside contact is independent of the connection via.

14. The microelectronic structure of claim 13, wherein the second wiring scheme comprises:
a second connection via that passes through the second backside source/drain, wherein the second connection via extends from a frontside surface of the second backside source/drain to a backside surface of the second backside source/drain, wherein the second backside source/drain surrounds the second connection via as it passes through the second backside source/drain.

15. The microelectronic structure of claim 14, wherein the second wiring scheme further comprises:
a second backside connection located on the backside surface of the second backside source/drain, wherein the second backside connection extends laterally across the backside surface of the second backside source/drain.

16. The microelectronic structure of claim 15, further comprising:
a second frontside contact connected to the second frontside source/drain.

17. The microelectronic structure of claim 16, wherein the second frontside contact extends laterally to connect with the second connection via.

18. The microelectronic structure of claim 17, wherein the second backside connection, the second connection via, and the second frontside contact form a shared contact, wherein the shared contact is in contact with a frontside surface of the second frontside source/drain, wherein portions of a sidewall of the shared contact are in contact with the second backside source/drain, and wherein the shared contact is in contact with a backside surface of the second backside source/drain.

19. The microelectronic structure of claim 18, further comprising:
a first backside cap located on the backside surface of the first backside connection; and
a second backside cap located on the backside surface of the second backside connection.

20. A microelectronic structure comprising:
a stacked FET that includes a first frontside source/drain, a second frontside source/drain, a first backside source/drain, and a second backside source/drain;
a first wiring scheme is utilized to make connections to the first frontside source/drain and the first backside source/drain;
a second wiring scheme is utilized to make connections to the second frontside source/drain and the second backside source/drain, wherein the first wiring scheme and the second wiring scheme are different wiring schemes;
wherein the first wiring scheme comprises;
a connection via that passes through the first backside source/drain, wherein the connection via extends from a frontside surface of the first backside source/drain to a backside surface of the first backside source/drain, wherein the first backside source/drain surrounds the connection via as it passes through the first backside source/drain;
a backside connection located on the backside surface of the first backside source/drain, wherein the backside connection extends laterally across the backside surface of the first backside source/drain; and
a backside cap located on the backside surface of the backside connection;
wherein the second wiring scheme comprises;
a backside contact in contact with a backside side surface of the second backside source/drain; and
a backside power distribution network is connected to the backside contact.
